(19) United States
(12) Patent Application Publication
(10) Pub. No.: US 2025/0372302 A1
(43) Pub. Date: Dec. 4, 2025

(54) CAPACITORS FOR A MICROELECTRONIC DEVICE HAVING INCREASED DENSITY AND RELATED METHODS

(71) Applicant: Micron Technology, Inc., Boise, ID (US)

(72) Inventors: Shyam Surthi, Boise, ID (US); Michele Piccardi, Cupertino, CA (US); Md Zahid Hossain, Boise, ID (US); Tejaswi K. Indukuri, Austin, TX (US)

(21) Appl. No.: 19/195,257

(22) Filed: Apr. 30, 2025

Related U.S. Application Data
(60) Provisional application No. 63/654,755, filed on May 31, 2024.

(51) Int. Cl. H01G 4/01; G11C 11/24

(52) U.S. Cl. CPC H01G 4/01; G11C 11/24

(57) ABSTRACT

A capacitor for a microelectronic device includes a first electrode and a second electrode. The first electrode includes a first base portion at a first level, a second base portion at a second level, first base contacts extending from the first to the second base portion, first plates extending from the first base portion, second plates extending from the second base portion, and capacitor plate contacts extending from the first plates to the second plates. The second electrode includes a first base portion formed at the first level, a second base portion formed at the second level, second base contacts extending from the first to the second base portion, first plates extending from the first base portion, second plates extending from the second base portion, and capacitor plate contacts extending from the first plates to the second plates. Additional capacitors and related methods are also disclosed.

### CROSS-REFERENCE TO RELATED APPLICATIONS

This application claims the benefit under 35 U.S.C. § 119 (e) of U.S. Provisional Patent Application Ser. No. 63/654,755, filed May 31, 2024, the disclosure of which is hereby incorporated herein in its entirety by this reference.

### TECHNICAL FIELD

Embodiments disclosed herein relate to electronic devices and electronic device fabrication. More particularly, embodiments of the disclosure relate to electronic devices, such as microelectronic devices having increased density of capacitors.

### BACKGROUND

Capacitors are electrical devices that store energy via electrical conductors (e.g., plates) separated by a dielectric (insulating) material. One of the electrical conductors may receive a positive charge and the other electrical conductor may receive a negative charge whereby the capacitor holds a charge. There are many types of capacitors used for a variety of applications. Such applications include memories, noise filtering, circuitry protection, and the like.

One example of a capacitor is a MIM capacitor. MIM capacitors operate as parallel plate capacitors in which metal plates (electrodes) are separated by a dielectric (insulating) material. MIM capacitors are known for providing stable capacitance and a high capacitance per unit area. Electronic devices include an array of memory cells that each include a storage node, such as a capacitor, and an access device, such as a transistor. Peripheral circuitry such as driver circuitry, decoders, sense amplifiers, etc., are used to access the memory cells in association with reading and/or writing data.

### BRIEF DESCRIPTION OF THE DRAWINGS

For a detailed understanding of the present disclosure, reference should be made to the following detailed description, taken in conjunction with the accompanying drawings, in which like elements have generally been designated with like numerals, and wherein:

FIG. 1 shows a schematic top view of a conventional capacitor for a microelectronic device;

FIG. 2 shows a schematic top view of a capacitor for a microelectronic device according to exemplary embodiments of the disclosure;

FIG. 3 shows a partial schematic top view of a capacitor for a microelectronic device, which may be either the conventional capacitor of FIG. 1 taken along the boxed region D or the capacitor according to exemplary embodiments of the disclosure of FIG. 2 taken along the boxed region D;

FIG. 4 shows a schematic isometric view of a conventional capacitor taken along the boxed region A from FIG. 3;

FIG. 5 shows a schematic isometric view of a capacitor according to exemplary embodiments of the disclosure taken along the boxed region A from FIG. 3;

FIG. 6A shows a schematic isometric view of a conventional capacitor, and FIG. 6B shows a schematic isometric section view of the conventional capacitor of FIG. 6A taken along the line B-B;

FIG. 7A shows a schematic isometric view of a capacitor according to exemplary embodiments of the disclosure, and FIG. 7B shows a schematic isometric section view of the capacitor of FIG. 7A taken along the line C-C;

FIG. 8A, FIG. 8B, and FIG. 8C show exemplary contact widths of contacts of a capacitor according to exemplary embodiments of the disclosure;

FIG. 9A, FIG. 9B, and FIG. 9C show exemplary contact lengths of contacts of a capacitor according to exemplary embodiments of the disclosure;

FIG. 10 shows a side view of a capacitor according to exemplary embodiments of the disclosure;

FIG. 11A, FIG. 11B, and FIG. 11C show an exemplary process flow for fabricating contacts of a capacitor according to exemplary embodiments of the disclosure;

FIG. 12A, FIG. 12B, and FIG. 12C show an exemplary process flow for fabricating contacts of a capacitor according to exemplary embodiments of the disclosure; and

FIG. 13 shows a schematic block diagram of an illustrative electronic system according to exemplary embodiments of disclosure.

### DETAILED DESCRIPTION

The illustrations presented herein are not actual views of any capacitor for a microelectronic device, or any component thereof, but are merely idealized representations, which are employed to describe embodiments of the disclosure.

The following description provides specific details, such as material types, material thicknesses, and process conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete description of an electronic device or a complete process flow for manufacturing the electronic device and the structures described below do not form a complete electronic device. Only those process acts and structures necessary to understand the embodiments described herein are described in detail below. Additional acts to form a complete electronic device may be performed by conventional techniques.

Unless otherwise indicated, the materials described herein may be formed by conventional techniques including, but not limited to, spin coating, blanket coating, chemical vapor deposition (CVD), atomic layer deposition (ALD), plasma-enhanced ALD, physical vapor deposition (PVD) (including sputtering, evaporation, ionized PVD, and/or plasma-enhanced CVD), or epitaxial growth. Alternatively, the materials may be grown in situ. Depending on the specific material to be formed, the technique for depositing or growing the material may be selected by a person of ordinary skill in the art. The removal of materials may be accomplished by any suitable technique including, but not limited to, etching (e.g., dry etching, wet etching, vapor etching), ion milling, abrasive planarization (e.g., chemical-mechanical planarization), or other known methods unless the context indicates otherwise.

Drawings presented herein are for illustrative purposes only and are not meant to be actual views of any particular material, component, structure, electronic device, or electronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the singular forms following “a,” “an,” and “the” are intended to include the plural forms as well, unless the context clearly indicates otherwise.

As used herein, “and/or” includes any and all combinations of one or more of the associated listed items.

As used herein, the term “may” with respect to a material, structure, feature, or method act indicates that such is contemplated for use in implementation of an embodiment of the disclosure, and such term is used in preference to the more restrictive term “is” so as to avoid any implication that other compatible materials, structures, features, and methods usable in combination therewith should or must be excluded.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the term “substantially” in reference to a given parameter, property, or condition means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “about” used in reference to a given parameter is inclusive of the stated value and has the meaning dictated by the context (e.g., it includes the degree of error associated with measurement of the given parameter, as well as variations resulting from manufacturing tolerances, etc.).

As used herein, the term “conductive material” means and includes an electrically conductive material. The conductive material may include, but is not limited to, one or more of a doped polysilicon, undoped polysilicon, a metal, an alloy, a conductive metal oxide, a conductive metal nitride, a conductive metal silicide, and a conductively doped semiconductor material. By way of example only, the conductive material may be one or more of tungsten (W), tungsten nitride (WN_{y}), nickel (Ni), tantalum (Ta), tantalum nitride (TaN_{y}), tantalum silicide (TaSiₓ), platinum (Pt), copper (Cu), silver (Ag), gold (Au), aluminum (Al), molybdenum (Mo), titanium (Ti), titanium nitride (TiN_{y}), titanium silicide (TiSiₓ), titanium silicon nitride (TiSiₓN_{y}), titanium aluminum nitride (TiAlₓN_{y}), molybdenum nitride (MoNₓ), iridium (Ir), iridium oxide (IrO_{z}), ruthenium (Ru), ruthenium oxide (RuO_{z}), n-doped polysilicon, p-doped polysilicon, undoped polysilicon, and conductively doped silicon.

As used herein, the term “configured” refers to a size, shape, material composition, and arrangement of one or more of at least one structure and at least one apparatus facilitating operation of one or more of the structure and the apparatus in a pre-determined way.

As used herein, the phrase “coupled to” refers to structures operably connected with each other, such as electrically connected through a direct ohmic connection or through an indirect connection (e.g., via another structure).

As used herein, the term “dielectric material” means and includes an electrically insulative material. The dielectric material may include, but is not limited to, one or more of an insulative oxide material or an insulative nitride material. A dielectric oxide may be an oxide material, a metal oxide material, or a combination thereof. The dielectric oxide may include, but is not limited to, a silicon oxide (SiOₓ, silicon dioxide (SiO₂)), phosphosilicate glass, borosilicate glass, borophosphosilicate glass, fluorosilicate glass, aluminum oxide (AlOₓ), gadolinium oxide (GdOₓ), hafnium oxide (HfOₓ), magnesium oxide (MgOₓ), niobium oxide (NbOₓ), tantalum oxide (TaOₓ), titanium oxide (TiOₓ), zirconium oxide (ZrOₓ), hafnium silicate, a dielectric oxynitride material (e.g., SiOₓN_{y}), a dielectric carboxynitride material (e.g., SiOₓC_{z}N_{y}), a combination thereof, or a combination of one or more of the listed materials with silicon oxide. A dielectric nitride material may include, but is not limited to, silicon nitride.

As used herein, the term “electronic device” includes, without limitation, a memory device, as well as semiconductor devices which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may, for example, be a 3D electronic device, such as a 3D NAND Flash memory device.

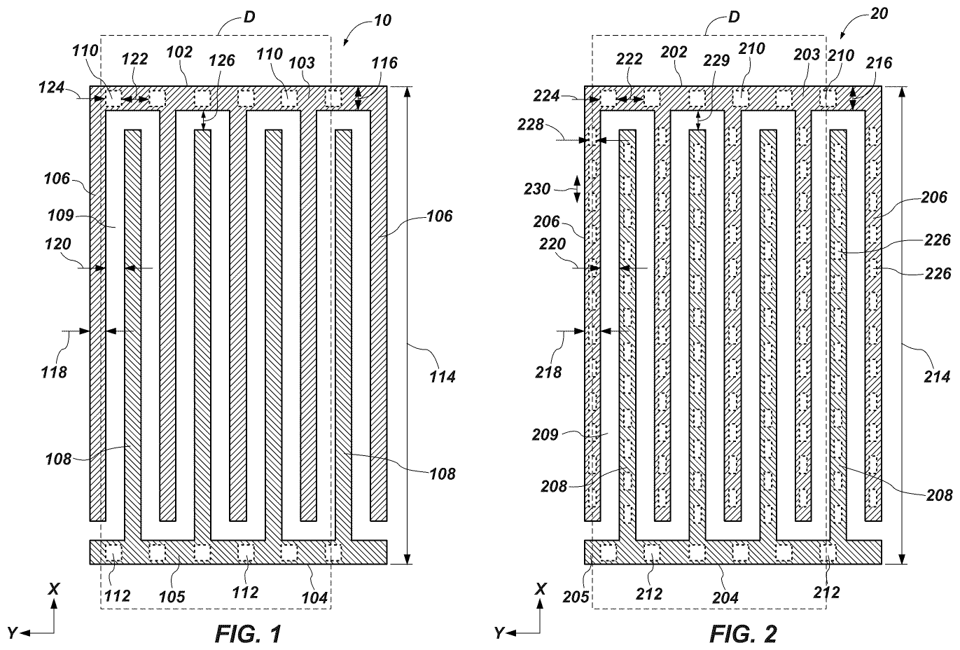

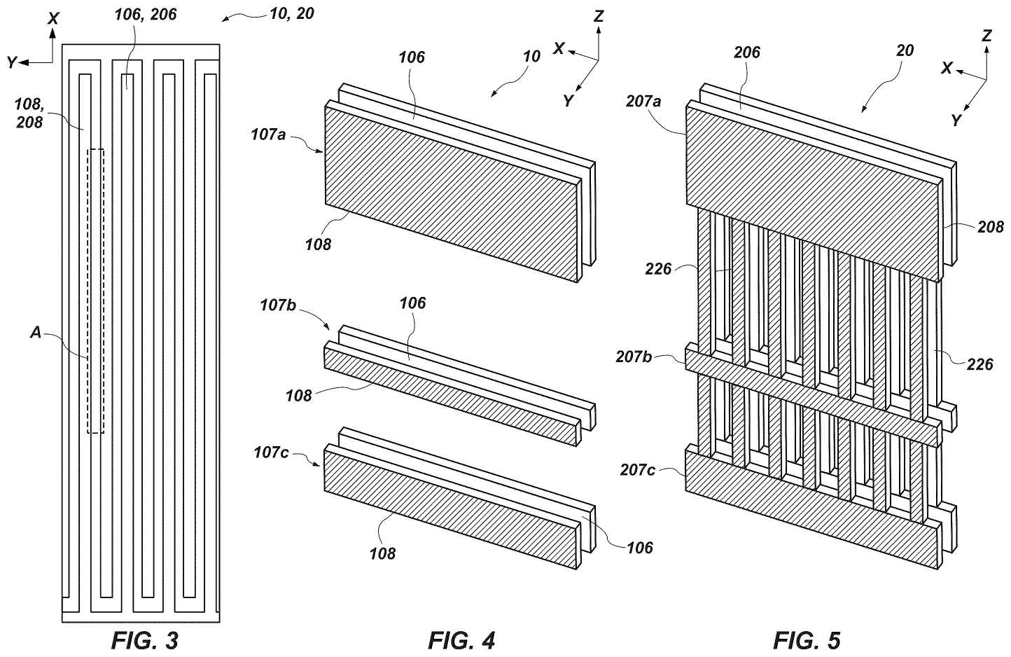

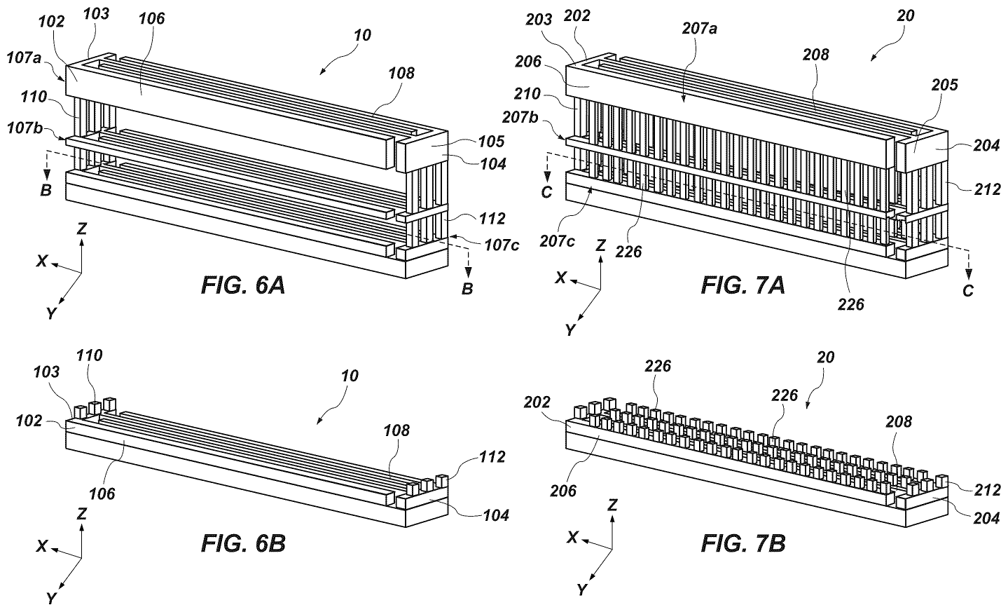

FIGS. 1, 4, 6A, and 6B show examples of a conventional capacitor 10 of an electronic device (e.g., a microelectronic device). The capacitor 10 may comprise a first electrode 102 and a second electrode 104. The first electrode 102 may comprise a plurality of plates 106 which extend from a base portion 103. The capacitor 10 may include multiple base portions 103 and the plurality of plates 106 at various levels, such as at a first level 107a, a second level 107b, and a third level 107c, as shown in FIGS. 4 and 6A. The second electrode 104 may also comprise a plurality of plates 108 extending from a base portion 105. The base portion 105 and the plurality of plates 108 may be at corresponding levels as those in the first electrode 102, such as at levels 107a, 107b, 107c, as shown in FIGS. 4 and 6A. The plates 106 of the first electrode 102 and the plates 108 of the second electrode 104 may interdigitate with one another, for example as shown in FIGS. 1, 4, 6A, and 6B, such that the first and second electrodes 102, 104 define first and second terminals, respectively, of the capacitor 10. In some examples, a dielectric material 109 may be disposed between the first and second electrodes 102, 104.

The base portion 103 of the first electrode 102 may comprise base contacts 110 that extend between the first level 107a and the second level 107b, and between the second level 107b and the third level 107c, of the base portion 103. Similarly, the base portion 105 of the second electrode 104 may comprise base contacts 112 that extend between the first level 107a and the second level 107b, and between the second level 107b and the third level 107c, of the base portion 105. The base contacts 110, 112 are configured to electrically couple the first, second, and third levels 107a, 107b, 107c of the base portions 103, 105 of the first and second electrodes 102, 104, respectively.

While not intended to be limiting, an exemplary capacitor may be configured to have a length 114 that is relatively long as compared to a width 116 of the base portion 103 or base portion 105. In some examples a length 114 may be about 300 or about 400 times longer than width 116 of the base portion 103 or base portion 105. The plates 106 of the first electrode 102 and the plates 108 of the second electrode 104 may be configured to have a width 118 substantially similar to or smaller than the width 116 of the base portions 103, 105. For example, a width 118 of the plates 106, 108 may be from about one-half to about equal to the width 116 of the base portions 103, 105. A width 120 of a distance between the plates 106 and the plates 108 (e.g., a width 120 of the dielectric material 109 between the plates 106, 108) may be similar to a width 118 of the plates 106, 108. The base contacts 110 on the base portion 103 of the first electrode 102 and the base contacts 112 on the base portion 105 of the second electrode 104 may be configured to have a square cross-section 124 similar in width to the width 118 of the plates 106, 108. The base contacts 110 on the base portion 103 of the first electrode 102 and the base contacts 112 on the base portion 105 of the second electrode 104 may have a distance 122 therebetween of about equal to a width 116 of the base portions 103, 105. Distal ends of each of the plates 106, 108 may be spaced at a distance 126 about equal to the width 116 the base portions 103, 105.

For example, while not intended to be limiting, an exemplary capacitor may be configured to have a length 114 of about 1000 dμm (wherein 1 dμm=50 nm). The base portion 103 of the first electrode 102 and the base portion 105 of the second electrode 104 may be configured to have a width 116 of about 3 dμm. The plates 106 of the first electrode 102 and the plates 108 of the second electrode 104 may be configured to have a width 118 of about 2 dμm. A width 120 of a distance between the plates 106 and the plates 108 (e.g., a width 120 of the dielectric material 109 between the plates 106, 108) may be about 2 dμm. The contacts 110 on the base portion 103 of the first electrode 102 and the base contacts 112 on the base portion 105 of the second electrode 104 may be configured to have a 2 dμm by 2 dμm square cross-section 124 (the base portion 105 may not be exactly square, as the square pattern may become rounded during subsequent processing and fabrication). The base contacts 110 on the base portion 103 of the first electrode 102 and the base contacts 112 on the base portion 105 of the second electrode 104 may have a distance 122 therebetween of about 3 dμm. Distal ends of each of the plates 106, 108 may be spaced at a distance 126 of about 3 dμm from a respective one of the base portions 103, 105.

FIGS. 2, 5, 7A, and 7B show examples of a capacitor 20 according to embodiments of the disclosure with increased capacitor density as compared to the conventional capacitor 10. The capacitor 20 may be a capacitor for a microelectronic device and may comprise a MIM capacitor, a MOM capacitor, a MOS capacitor, or the like. In some embodiments, the capacitor 20 is a MIM capacitor. The capacitor 20 may comprise a first electrode 202 and a second electrode 204. The first electrode 202 may comprise a plurality of plates 206 (e.g., fingers, combs) which extend vertically from a base portion 203. The base portion 203 and the plurality of plates 206 may be formed at various levels, such as at a first level 207a, a second level 207b, and a third level 207c, as shown in FIGS. 5 and 7A. Accordingly, the base portion 203 at the first level 207a may be termed a first base portion, the base portion 203 at the second level 207b may be termed a second base portions, and the base portion at the third level may be termed a third base portion. Similarly, the plates 206 formed at the first level may be termed first plates, the plates 206 formed at the second level may be termed second plates, and the plates 206 formed at the third level may be termed third plates.

A distance between the vertically adjacent levels 207a and 207b, and between the vertically adjacent levels 207b and 207c may be uniform or the vertically adjacent levels 207a, 207b, 207c may be spaced apart by different distances. By way of example only, the distance between the first level 207a, the second level 207b, and the third level 207c may range from about 200 nm to about 800 nm, such as from about 300 nm to about 600 nm.

The second electrode 204 may also comprise a plurality of plates 208 extending from a base portion 205. The base portion 205 and the plurality of plates 208 may be formed at corresponding levels as those in the first electrode 202, such as at levels 207a, 207b, 207c, as shown in FIGS. 5 and 7A. Accordingly, the base portion 205 at the first level 207a may be termed a first base portion, the base portion 205 at the second level 207b may be termed a second base portions, and the base portion at the third level may be termed a third base portion. Similarly, the plates 208 formed at the first level may be termed first plates, the plates 208 formed at the second level may be termed second plates, and the plates 208 formed at the third level may be termed third plates.

While three levels 207a, 207b, 207c are shown in FIGS. 5 and 7A, there may be only two levels or there may be more than three levels. By way of example only, the levels of the capacitor 20 may include other contact structures, routing structures, gates, source regions, drain regions, or complementary metal-oxide-semiconductor (CMOS) circuitry. The plates 206 of the first electrode 202 and the plates 208 of the second electrode 204 may interdigitate with one another, for example as shown in FIGS. 2, 5, 7A, and 7B, such that the first and second electrodes 202, 204 form first and second terminals, respectively, of the capacitor 20. In some examples, a dielectric material 209 may be disposed between the first and second electrodes 202, 204.

The base portion 203 of the first electrode 202 may comprise first base contacts 210 that extend between the first level 207a and the second level 207b, and between the second level 207b and the third level 207c, of the base portion 203. Similarly, the base portion 205 of the second electrode 204 may comprise second base contacts 212 that extend between the first level 207a and the second level 207b, and between the second level 207b and the third level 207c, of the base portion 205. The first and second base contacts 210, 212 are configured to electrically couple the first, second, and third levels 207a, 207b, 207c of the base portions 203, 205 of the first and second electrodes 202, 204, respectively. In other words, the first base contacts 210, are configured to electrically couple the first, second, and third base portions of the first base portion 203 of the first electrode 202, and the second base contacts 212 are configured to electrically couple the first, second, and third base portions of the second base portion 205 of the second electrode 204.

While not intended to be limiting, an exemplary capacitor 20 may be configured to have a length 214 that is relatively long as compared to a width 216 of the base portion 203 or base portion 205. In some examples a length 214 may be around 300 or 400 times longer than width 216 of the base portion 203 or base portion 205. The plates 206 of the first electrode 202 and the plates 208 of the second electrode 204 may be configured to have a width 218 substantially similar to or smaller than the width 216 of the base portions 203, 205. For example, a width 218 of the plates 206, 208 may be about one-half to about equal to the width 216 of the base portions 203, 205. A width 220 of a distance between the plates 206 and the plates 208 (e.g., a width 220 of the dielectric material 209 between the plates 206, 208) may be similar to a width 218 of the plates 206, 208. The first base contacts 210 on the base portion 203 of the first electrode 202 and the second base contacts 212 on the base portion 205 of the second electrode 204 may be configured to have a square cross-section 224 similar in width to the width 218 of the plates 206, 208. The first base contacts 210 on the base portion 203 of the first electrode 202 and the second base contacts 212 on the base portion 205 of the second electrode 204 may have a distance 222 therebetween of about equal to a width 216 of the base portions 203, 205. Distal ends of each of the plates 206, 208 may be spaced at a distance 229 about equal to the width 216 the base portions 103, 105.

For example, while not intended to be limiting, an exemplary capacitor 20 may be configured to have a length 214 of about 1000 dμm. The base portion 203 of the first electrode 202 and the base portion 205 of the second electrode 204 may be configured to have a width 216 of about 3 dμm. The plates 206 of the first electrode 202 and the plates 208 of the second electrode 204 may be configured to have a width 218 of about 2 dμm. A width 220 of a distance between the plates 206 and the plates 208 (e.g., a width 220 of the dielectric material 209 between the plates 206, 208) may be about 2 dμm. The first base contacts 210 on the base portion 203 of the first electrode 202 and the second base contacts 212 on the base portion 205 of the second electrode 204 may be configured to have a 2 dμm by 2 dμm square cross-section 224. The first base contacts 210 on the base portion 203 of the first electrode 202 and the second base contacts 212 on the base portion 205 of the second electrode 204 may have a distance 222 therebetween of about 3 dμm. Distal ends of each of the plates 206, 208 may be spaced at a distance 229 of about 3 dμm from a respective one of the base portions 203, 205.

To increase the capacitor density of the capacitor 20 as compared to a conventional capacitor 10 without changing the integration scheme, the capacitor 20 may further comprise a plurality of capacitor plate contacts 226. As shown in FIGS. 2, 5, 7A, and 7B, multiple capacitor plate contacts 226 are present along a length of the plates 206 of the first electrode 202 and the plates 208 of the second electrode 204. As shown in FIGS. 5 and 7A, the capacitor plate contacts 226 may extend from the first level 207a of the plates 206 of the first electrode 202 to the second level 207b of the plates 206 of the first electrode 202, and from the second level 207b of the plates 206 of the first electrode 202 to the third level 207c of the plates 206 of the first electrode 202. Similarly, capacitor plate contacts 226 may extend from the first level 207a of the plates 208 of the second electrode 204 to the second level 207b of the plates 208 of the second electrode 204, and from the second level 207b of the plates 208 of the second electrode 204 to the third level 207c of the plates 208 of the second electrode 204. In other words, the capacitor plate contacts 226 may electrically couple the first, second, and third plates of the plates 206 of the first electrode 202, and the capacitor plate contacts 226 may electrically couple the first, second, and third plates of the plates 208 of the second electrode 204.

The capacitor plate contacts 226 are shown in FIGS. 2, 5, 7A, and 7B as having a uniform pitch. By way of example only, the pitch of the capacitor plate contacts 226 may be from about 60 nm to about 110 nm, such as from about 60 nm to about 80 nm or from about 80 nm to about 100 nm. The pitch of the capacitor plate contacts 226 may be tailored depending on desired spacing between the first electrode 202 and the second electrode 204. While FIGS. 2, 5, 7A, and 7B show the capacitor plate contacts 226 being uniformly spaced on the first and second electrodes 202, 204 of the capacitor 20, the spacing between adjacent capacitor plate contacts 226 may vary. Additionally, while FIGS. 5 and 7A show that the capacitor plate contacts 226 between the levels 207a, 207b, 207c are vertically aligned with one another, the capacitor plate contacts 226 between the levels 207a, 207b and between the levels 207b, 207c may be vertically offset from one another.

With the addition of the capacitor plate contacts 226 along the plates 206, 208 (e.g., fingers, combs) of the first electrode 202 and the second electrode 204, the density and performance of the capacitor 20 may increase by a minimum of from about 25% to about 30% as compared to the conventional capacitor 10, which includes base contacts 110, 112 only on the base portions 103, 105. The capacitor plate contacts 226 enable increased capacitance between the electrodes 202, 204 by increasing a total surface area of each of the electrodes 202, 204 (e.g., the terminals) of the capacitor 20. Without being bound by any theory, it is believed that the capacitor plate contacts 226 on the first electrode 202 and the second electrode 204 provide fringe field effect, which increases the capacitance of the capacitor 20. Although the capacitor plate contacts 226 do not form a continuous plate, the fringe field effect is achieved. The increased density and performance may be achieved without adding cost. In addition, the capacitor 20 may be formed by a similar process as the conventional capacitor 10. Therefore, the capacitor 20 may be formed without substantial changes to the process. By utilizing the capacitor plate contacts 226, the capacitor plate contacts 226 may function as a parallel plate capacitor between the levels 207a, 207b, and 207c of the capacitor 20.

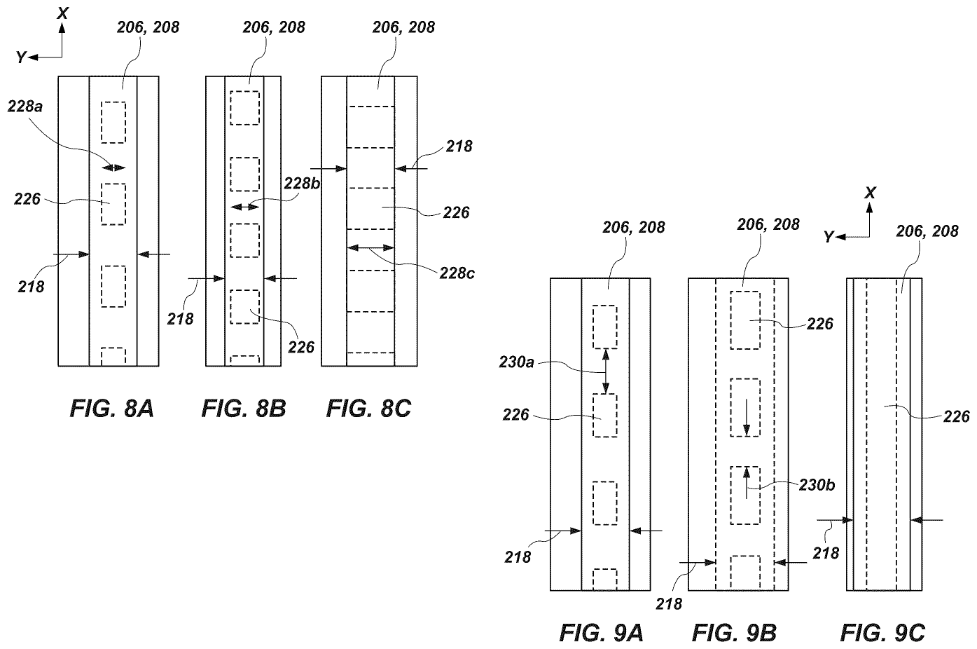

While FIGS. 2, 5, 7A, and 7B show an example of a configuration of capacitor plate contacts 226 on the first and second electrodes 202, 204 of the capacitor 20, different configurations of the capacitor plate contacts 226 are possible, as shown in FIGS. 8A-9C. FIGS. 8A-9C show different configurations of the capacitor plate contacts 226 on either of the plates 206, 208 of the capacitor electrodes 202, 204. The capacitor plate contacts 226 may be configured with a width 228, as shown in FIGS. 8A-8C, and separated by a distance 230, as shown in FIGS. 9A-9C, between adjacent capacitor plate contacts 226. As shown in the configurations of FIGS. 8A-8C, the width 228 of the capacitor plate contacts 226 may be different (e.g., less than as shown in FIGS. 8A and 8B) or the same as (as shown in FIG. 8C) a width 218 of the plates 206, 208. For example, in FIG. 8A, a width 228a of the capacitor plate contacts 226 may be configured to be about half of a width 218 of the plates 206, 208. In one example, the width 218 of the plates 206, 208 may be about 2 dμm and the width 228a of the capacitor plate contacts 226 may be about 1 dμm.

In another example shown in FIG. 8B, a width 228b of the capacitor plate contacts 226 may be configured to be about three-quarters of a width 218 of the plates 206, 208. In one example, the width 218 of the plates 206, 208 may be about 2 dμm and the width 228b of the capacitor plate contacts 226 may be about 1.5 dμm.

In another example shown in FIG. 8C, a width 228c of the capacitor plate contacts 226 may be configured to be about the same as a width 218 of the plates 206, 208. In one example, the width 218 of the plates 206, 208 may be about 2 dμm and the width 228c of the capacitor plate contacts 226 may be about 2 dμm.

When the width 228 of the capacitor plate contacts 226 increases, the capacitance of the capacitor 20 increases. However, as the width 228 of the capacitor plate contacts 226 increases, there may be an increased likelihood of the capacitor plate contacts 226 falling off of (e.g., not properly aligning with) one of the levels 207a, 207b, 207c of the plates 206, 208 during processing. This may result in an increased likelihood for a short circuit between the plates 206, 208. In some examples, a significant increase in capacitance may be achieved using capacitor plate contacts 226 exhibiting a width 228a substantially equal to one-half of a width 218 of the plates 206, 208, such as shown in FIG. 8A, while also minimizing the likelihood of misalignment between the capacitor plate contacts 226 and one of the levels 207a, 207b, 207c.

As shown in FIGS. 9A-9C, the distance 230 between neighboring capacitor plate contacts 226 may be configured at different lengths with respect to a width 218 of either of the plates 206, 208. For example, in FIG. 9A, the distance 230a between adjacent capacitor plate contacts 226 may be about equal to a width 218 of the plates 206, 208. In one example, the width 218 of the plates 206, 208 may be about 2 dμm and the distance 230a between the capacitor plate contacts 226 may be about 2 dμm.

In another example shown in FIG. 9B, a distance 230b between the capacitor plate contacts 226 may be about one-half of a width 218 of the plates 206, 208. In one example, the width 218 of the plates 206, 208 may be about 2 dμm and the distance 230a between the capacitor plate contacts 226 may be about 1 dμm.

In another example shown in FIG. 9C, no distance may be between adjacent capacitor plate contacts 226. In other words, the capacitor plate contacts 226 may form a substantially continuous plate extending from a first level 207a to a second level 207b, or from a second level 207b to a third level 207c of the plates 206, 208.

When the distance 230 between the capacitor plate contacts 226 decreases, a capacitance of the capacitor 20 increases. It has been found, however, that the effect of the decrease in distance 230 between the capacitor plate contacts 260 has a smaller effect on the capacitance of the capacitor 20 as compared to the increase in the width 228 of the capacitor plate contacts 226 relative to the width 218 of the plates 206, 208. In some examples, decreasing the distance 230 between the capacitor plate contacts 226 may introduce added complexity to the fabrication of the capacitor 20. In some examples, a significant increase in capacitance may be achieved with a distance 230a between capacitor plate contacts 226 having a length about equal to a width 218 of the plates 206, 208, such as shown in FIG. 9A, without introducing substantial changes to a process of forming the capacitor 20. The capacitor 20 may, therefore, be formed without a different or complex process.

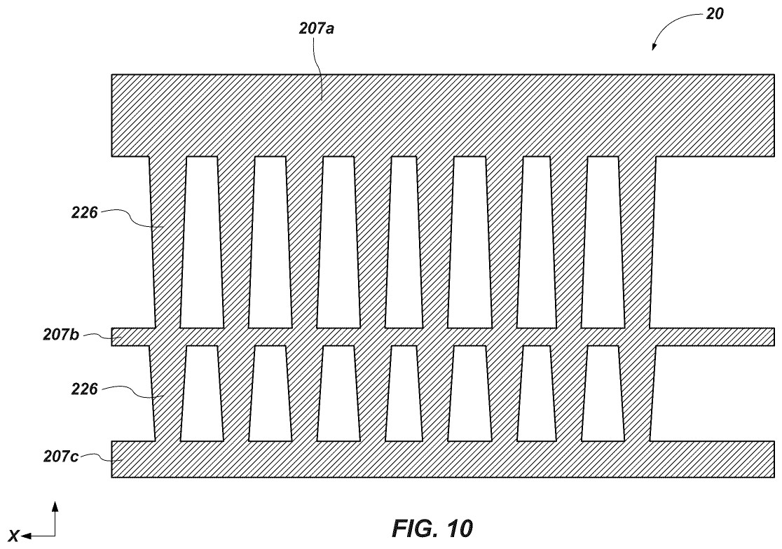

In some examples as shown in FIG. 2, the capacitor plate contacts 226 on the plates 206 of the first electrode 202 may be offset in the x-direction from the capacitor plate contacts 226 of the plates 208 of the second electrode 204. In other examples, the capacitor plate contacts 226 on the plates 206 of the first electrode 202 may be substantially aligned in the x-direction with the capacitor plate contacts 226 of the plates 208 of the second electrode 204. In some examples, as shown in FIG. 10, the capacitor plate contacts 226 may exhibit sloped sidewalls (e.g., a taper) from a top to a bottom of the capacitor plate contacts 226 for convenience in fabrication and to ensure that the capacitor plate contacts 226 land on one of the levels 207b, 207c of the plates 206, 208 of the capacitor 20. Therefore, critical dimension (CD) of an upper portion of the capacitor plate contacts 226 may be relatively greater than a CD of a lower portion of the capacitor plate contacts 226. In some examples, the slope of the capacitor plate contacts 226 from the third level 207c of the plates 206, 208 to the second level 207b of the plates 206, 208 may be between about 80 degrees and 90 degrees from a plane parallel to the levels 207a, 207b, 207c (e.g., the x-direction in FIG. 10). In some examples, the slope of the capacitor plate contacts 226 from the third level 207c of the plates 206, 208 to the second level 207b of the plates 206, 208 may be about 88 degrees from a plane parallel to the levels 207a, 207b, 207c (e.g., the x-direction in FIG. 10). In some examples, the slope of the capacitor plate contacts 226 from the second level 207b of the plates 206, 208 to the first level 207a of the plates 206, 208 may be between about 80 degrees and 90 degrees from a plane parallel to the levels 207a, 207b, 207c (e.g., the x-direction in FIG. 10). In some examples, the slope of the capacitor plate contacts 226 from the second level 207b of the plates 206, 208 to the first level 207a of the plates 206, 208 may be about 89 degrees from a plane parallel to the levels 207a, 207b, 207c (e.g., the x-direction in FIG. 10).

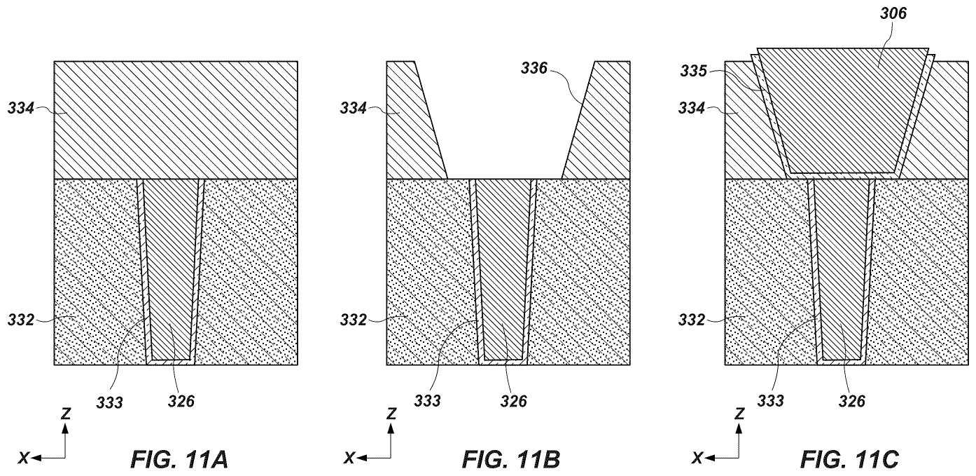

As mentioned above, the capacitor plate contacts 226 of the capacitor 20 may be formed without changes to the integration scheme of the capacitor 20. The methods of forming the capacitor plate contacts 226, 326, 426 may be robust to underetch since the capacitor plate contacts 226, 326, 426 may form a shield due to the proximity of electrical field lines. The capacitor plate contacts 226 may be formed utilizing any suitable method. FIGS. 11A-11C show an example of forming a capacitor plate contact 326 according to embodiments of the disclosure. The capacitor plate contact 326 may be similar to the capacitor plate contacts 226 shown in FIGS. 2, 5, 7A, and 7B, as described above. The capacitor plate contact 326 may electrically connect a plate 306 at one level to a plate 306 at another level (e.g., an overlying level, an underlying level). The plate 306 or line may be similar to the plates 206 of the first electrode 202. While not shown in FIGS. 10A-10C, a plate or line similar to the plates 208 of the second electrode 204 may be present laterally adjacent to the plate 306.

In FIG. 11A, a capacitor plate contact 326 may be formed from a conductive material such as those as described above. The capacitor plate contact 326 may be surrounded by a first dielectric material 332 such as those described above. By way of example only, openings (not shown) may be formed in the first dielectric material 332 by conventional photolithography techniques. The openings may substantially correspond in size and shape to a size and shape of the capacitor plate contacts 326 to be formed therein. A liner 333 may be formed in the openings before forming the conductive material of the capacitor plate contact 326. The capacitor plate contact 326 and first dielectric material 332 may be formed using any suitable microfabrication process such as CVD, ALD, PVD, or the like. The capacitor plate contact 326 and first dielectric material 332 may be formed over a base structure (not shown). The base structure may be a base material or construction upon which additional features (e.g., materials, structures, devices) of the microelectronic device are formed. The base structure may include one or more materials, structures, and/or regions formed therein and/or thereon. The base structure may comprise a semiconductor structure (e.g., a semiconductor wafer), or a base semiconductor material on a supporting structure. For example, the base structure may comprise a conventional silicon substrate (e.g., a conventional silicon wafer), or another bulk substrate comprising a semiconductor material. Alternatively, the base structure may comprise a conductive structure. In some embodiments, the base structure includes one or more conductive features, structures, and/or regions formed therein and/or thereon. A second dielectric material 334 may be formed over the capacitor plate contact 326 and the first dielectric material 332 as shown in FIG. 11A. The second dielectric material 334 may be formed from the same material as the first dielectric material 332 or may be formed from a separate dielectric material.

As shown in FIG. 11B, a trench 336 may be formed in the second dielectric material 334 adjacent (e.g., directly adjacent) the capacitor plate contact 326. The trench 336 may be formed using any suitable microfabrication process such as by patterning the second dielectric material 334 using photolithography and etching. The trench 336 may substantially correspond in size and shape to a size and shape of a plate 306 or line to be formed therein. A liner 335 may be formed in the trench 336 before forming the plate 306. As shown in FIG. 11C, a plate 306 or line may be formed of a conductive material adjacent the capacitor plate contact 326 and in the trench 336. The plate 306 may be in electrical contact with the capacitor plate contact 326. Additional semiconductor features may subsequently be formed over the plate 306 and the second dielectric material 334 corresponding to overlying levels 207a, 207b, 207c of a microelectronic device.

Accordingly, in some embodiments, a capacitor for a microelectronic device comprises a first electrode and a second electrode. The first electrode comprises a first base portion at a first level, a second base portion at a second level, first base contacts extending from the first base portion to the second base portion, one or more first plates extending from the first base portion, one or more second plates extending from the second base portion, and capacitor plate contacts extending from the one or more first plates to the one or more second plates. The second electrode comprises a first base portion formed at the first level, a second base portion formed at the second level, second base contacts extending from the first base portion to the second base portion, one or more first plates extending from the first base portion, one or more second plates extending from the second base portion, and capacitor plate contacts extending from the one or more first plates to the one or more second plates.

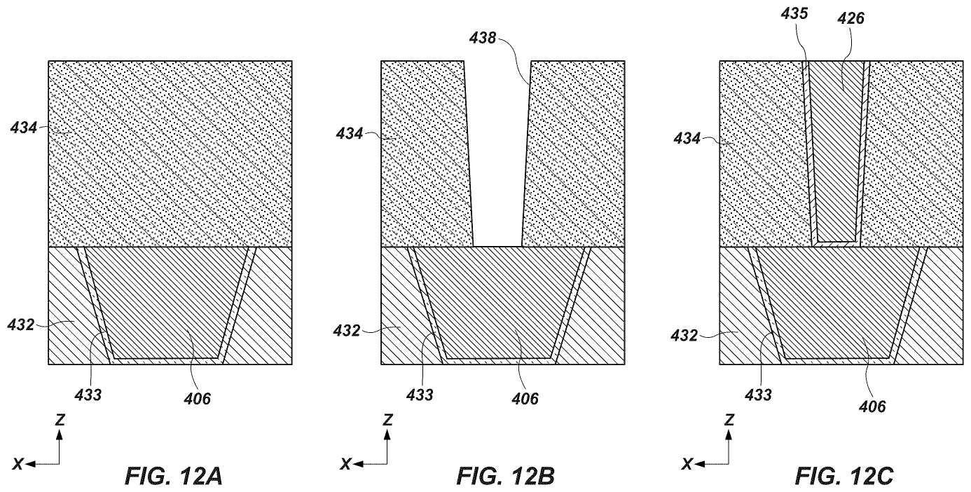

FIGS. 12A-12C show another example of fabricating a capacitor plate contact 426. The capacitor plate contact 426 may be similar to the capacitor plate contacts 226 shown in FIGS. 2, 5, 7A, and 7B, as described above. In other words, the capacitor plate contact 326 may electrically connect a plate 306 at one level to a plate 306 at another level (e.g., an overlying level, an underlying level). The plate 406 or line may be similar to the plates 206 of the first electrode 202. While not shown in FIGS. 12A-12C, a plate or line similar to the plates 208 of the second electrode 204 may be present laterally adjacent to the plate 406.

In FIG. 12A, a plate 406 or line may be formed from a conductive material. The plate 406 may be surrounded by a first dielectric material 432. The plate 406 may be surrounded by a first dielectric material 432 such as those described above. By way of example only, openings (not shown) may be formed in the first dielectric material 432 by conventional photolithography techniques. The openings may substantially correspond in size and shape to a size and shape of the plate 406 formed therein. A liner 433 may be formed in the openings before forming the conductive material of the plate 406. The plate 406 and the first dielectric material 432 may be formed using any suitable microfabrication process such as CVD, ALD, PVD, or the like. The plate 406 and first dielectric material 432 may be formed over a base structure (not shown). The base structure may be a base material or construction upon which additional features (e.g., materials, structures, devices) of the microelectronic device are formed. The base structure may include one or more materials, structures, and/or regions formed therein and/or thereon. The base structure may comprise a semiconductor structure (e.g., a semiconductor wafer), or a base semiconductor material on a supporting structure. For example, the base structure may comprise a conventional silicon substrate (e.g., a conventional silicon wafer), or another bulk substrate comprising a semiconductor material. Alternatively, the base structure may comprise a conductive structure. In some embodiments, the base structure includes one or more conductive features, structures, and/or regions formed therein and/or thereon. Second dielectric material 434 may be formed over the plate 406 and the first dielectric material 432 as shown in FIG. 12A. The second dielectric material 434 may be formed from the same material as the first dielectric material 432 or may be formed from a separate dielectric material.

As shown in FIG. 12B, a trench 438 may be formed in the second dielectric material 434 adjacent (e.g., directly adjacent) the plate 406. The trench 438 may be formed using any suitable microfabrication process such as by patterning the second dielectric material 434 using photolithography and etching. The trench 438 may substantially correspond in size and shape to a size and shape of a capacitor plate contact 426 to be formed therein. A liner 435 may be formed in the trench 438 before forming the capacitor plate contact 426. As shown in FIG. 12C, a capacitor plate contact 426 may be formed of a conductive material adjacent to the plate 406 and in the trench 438. The capacitor plate contact 426 may be in electrical contact with the plate 406. Additional semiconductor features may subsequently be formed over the capacitor plate contact 426 and the second dielectric material 434 corresponding to overlying levels 207a, 207b, 207c of a microelectronic device.

The capacitor plate contacts 326, 426 shown in FIGS. 11C and 12C may be used to electrically connect plates 306, 406 at one level to plates 306, 406 at another level (e.g., an overlying level, an underlying level). In other words, the plates 306, 406 at a level corresponding to level 207a may be electrically connected by the capacitor plate contacts 326, 426 to a level corresponding to level 207b. Similarly, the plates 306, 406 at a level corresponding to level 207b may be electrically connected by the capacitor plate contacts 326, 426 to a level corresponding to level 207c.

Accordingly, in some embodiments, a method of fabricating a capacitor for a microelectronic device comprises forming first electrode plates of a first capacitor electrode at a first level, forming first capacitor plate contacts that connect to and extend from the first electrode plates, forming second electrode plates of a second capacitor electrode at the first level, and forming second capacitor plate contacts that connect to and extend from the second electrode plates. The method further comprises forming third electrode plates of the first capacitor electrode at a second level and aligned with the first electrode plates, the third electrode plates being formed adjacent to the first capacitor plate contacts, and the first capacitor plate contacts electrically coupling the first electrode plates and the third electrode plates. The method further comprises forming fourth electrode plates of the second capacitor electrode at the second level and aligned with the second electrode plates, the fourth electrode plates being formed adjacent to the second capacitor plate contacts, and the second capacitor plate contacts electrically coupling the second electrode plates and the fourth electrode plates.

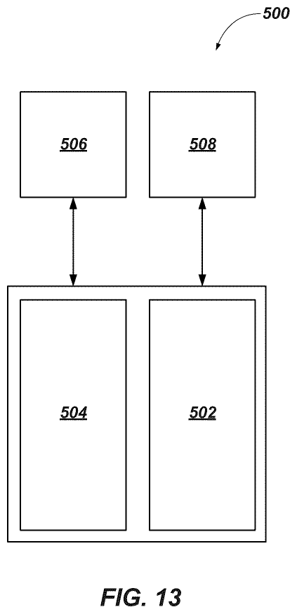

Capacitors (e.g., the capacitor 20 (FIGS. 2, 3, 5, 7A, and 7B)) in accordance with embodiments of the disclosure may be used in embodiments of electronic systems of the disclosure. For example, FIG. 13 is a schematic block diagram of an illustrative electronic system 500 according to embodiments of disclosure. The electronic system 500 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 500 includes at least one memory device 502. The memory device 502 may include, for example, one or more capacitors (e.g., the capacitors 20 (FIGS. 2, 3, 5, 7A, and 7B)) previously described herein. The electronic system 500 may further include at least one electronic signal processor device 504 (often referred to as a “microprocessor”). The electronic signal processor device 504 may, optionally, comprise a capacitor (e.g., the capacitor 20 (FIGS. 2, 3, 5, 7A, and 7B)) previously described herein. While the memory device 502 and the electronic signal processor device 504 are depicted as two (2) separate devices in FIG. 13, in additional embodiments, a single (e.g., only one) memory/processor device having the functionalities of the memory device 502 and the electronic signal processor device 504 is included in the electronic system 500. In such embodiments, the memory/processor device may include a capacitor (e.g., the capacitor 20 (FIGS. 2, 3, 5, 7A, and 7B)) previously described herein. The electronic system 500 may further include one or more input devices 506 for inputting information into the electronic system 500 by a user, such as, for example, a mouse or other pointing device, a keyboard, a touchpad, a button, or a control panel. The electronic system 500 may further include one or more output devices 508 for outputting information (e.g., visual or audio output) to a user such as, for example, a monitor, a display, a printer, an audio output jack, and/or a speaker. In some embodiments, the input device 506 and the output device 508 comprise a single touchscreen device that can be used both to input information to the electronic system 500 and to output visual information to a user. The input device 506 and the output device 508 may communicate electrically with one or more of the memory device 502 and the electronic signal processor device 504.

Accordingly, in some embodiments, an electronic system comprises an input device, an output device a processor device operably connected to the input device and the output device, and a memory device operably connected to the processor device. The memory device includes a capacitor for a microelectronic device including first electrode plates disposed at a first level and second electrode plates disposed at the first level, the second electrode plates interdigitating with the first electrode plates. The capacitor further includes third electrode plates disposed at a second level and aligned with the first electrode plates and fourth electrode plates disposed at the second level and aligned with the second electrode plates, the fourth electrode plates interdigitating with the third electrode plates. The capacitor further includes first capacitor plate contacts extending from the first electrode plates to the third electrode plates and electrically coupling the first electrode plates and the third electrode plates and second capacitor plate contacts extending from the second electrode plates to the fourth electrode plates and electrically coupling the second electrode plates and the fourth electrode plates.

The capacitor 20 may thus provide an increase in capacitor density without added costs and without change to the integration scheme of a capacitor. In some examples, a minimum gain of capacitance may be around 35%-30%. The capacitor 20 may be scaled to different sizes based on an application. The capacitor 20 may also provide for a resilient design and may provide the above advantages even when random underetch of one or more capacitor plate contacts occurs during fabrication.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A capacitor for a microelectronic device comprising:
a first electrode comprising:
a first base portion at a first level,
a second base portion at a second level,
first base contacts extending from the first base portion to the second base portion,
one or more first plates extending from the first base portion,
one or more second plates extending from the second base portion, and
capacitor plate contacts extending from the one or more first plates to the one or more second plates; and
a second electrode comprising:
a first base portion formed at the first level,
a second base portion formed at the second level,
second base contacts extending from the first base portion to the second base portion,
one or more first plates extending from the first base portion,
one or more second plates extending from the second base portion, and
capacitor plate contacts extending from the one or more first plates to the one or more second plates.

2. The capacitor of claim 1, wherein the capacitor plate contacts of the first electrode exhibit a width of about ½ a width of the one or more first plates and the one or more second plates of the first electrode, and wherein the capacitor plate contacts of the second electrode exhibit a width of about ½ a width of the one or more first plates and the one or more second plates of the second electrode.

3. The capacitor of claim 1, wherein the capacitor plate contacts of the first electrode exhibit a width of about ¾ a width of the one or more first plates and the one or more second plates of the first electrode, and wherein the capacitor plate contacts of the second electrode exhibit a width of about ¾ a width of the one or more first plates and the one or more second plates of the second electrode.

4. The capacitor of claim 1, wherein the capacitor plate contacts of the first electrode exhibit a width that is about equal to a width of the one or more first plates and the one or more second plates of the first electrode, and wherein the capacitor plate contacts of the second electrode exhibit a width that is about equal to a width of the one or more first plates and the one or more second plates of the second electrode.

5. The capacitor of claim 1, wherein a distance between adjacent capacitor plate contacts of the capacitor plate contacts of the first electrode is about equal to a width of the one or more first plates and the one or more second plates of the first electrode, and wherein a distance between the capacitor plate contacts of the second electrode is about equal to a width of the one or more first plates and the one or more second plates of the second electrode.

6. The capacitor of claim 1, wherein a distance between the capacitor plate contacts of the first electrode exhibits a length that is about ½ of a width of the one or more first plates and the one or more second plates of the first electrode, and wherein a distance between the capacitor plate contacts of the second electrode exhibits a length that is about ½ of a width of the one or more first plates and the one or more second plates of the second electrode.

7. The capacitor of claim 1, wherein the capacitor plate contacts of the first electrode exhibit a tapered cross-sectional profile and wherein the capacitor plate contacts of the second electrode exhibit a tapered cross-sectional profile.

8. The capacitor of claim 7, wherein the taper is about 88 degrees or about 89 degrees.

9. The capacitor of claim 1, wherein the capacitor plate contacts of the first electrode are offset from the capacitor plate contacts of the second electrode.

10. An electronic system comprising:
an input device;
an output device;
a processor device operably connected to the input device and the output device; and
a memory device operably connected to the processor device and comprising:
a capacitor comprising:
first electrode plates disposed at a first level;
second electrode plates disposed at the first level, the second electrode plates interdigitating with the first electrode plates;
third electrode plates disposed at a second level and aligned with the first electrode plates;
fourth electrode plates disposed at the second level and aligned with the second electrode plates, the fourth electrode plates interdigitating with the third electrode plates;
first capacitor plate contacts extending from the first electrode plates to the third electrode plates and electrically coupling the first electrode plates and the third electrode plates; and
second capacitor plate contacts extending from the second electrode plates to the fourth electrode plates and electrically coupling the second electrode plates and the fourth electrode plates.

11. The electronic system of claim 10, wherein the capacitor further comprises:
a first base portion disposed at the first level, the first electrode plates extending from the first base portion;
a second base portion disposed at the first level, the second electrode plates extending from the second base portion;
a third base portion disposed at the second level, the third electrode plates extending from the third base portion; and
a fourth base portion disposed at the second level, the fourth electrode plates extending from the fourth base portion, wherein
the first base portion, the first electrode plates, the third base portion, the third electrode plates, and the first capacitor plate contacts define a first electrode of the capacitor, and
the second base portion, the second electrode plates, the fourth base portion, the fourth electrode plates, and the second capacitor plate contacts define a second electrode of the capacitor.

12. The electronic system of claim 11, wherein the capacitor further comprises:
first base contacts extending from the first base portion to the third base portion and electrically coupling the first base portion to the third base portion; and
second base contacts extending from the second base portion to the fourth base portion and electrically coupling the second base portion to the fourth base portion.

13. The electronic system of claim 12, wherein the capacitor further comprises:
fifth electrode plates disposed at a third level and aligned with the first electrode plates; and
third capacitor plate contacts extending from the third electrode plates to the fifth electrode plates and electrically coupling the third electrode plates and the fifth electrode plates.

14. The electronic system of claim 13, wherein the capacitor further comprises:
sixth electrode plates disposed at a third level and aligned with the second electrode plates, the sixth electrode plates interdigitating with the fifth electrode plates; and
fourth capacitor plate contacts extending from the fourth electrode plates to the sixth electrode plates and electrically coupling the fourth electrode plates and the sixth electrode plates.

15. The electronic system of claim 14, wherein the capacitor further comprises:
a fifth base portion disposed at the third level, the fifth electrode plates extending from the fifth base portion; and
a sixth base portion disposed at the third level, the sixth electrode plates extending from the sixth base portion.

16. The electronic system of claim 15, wherein:
the fifth base portion, the fifth electrode plates, and the third capacitor plate contacts define a portion of the first electrode of the capacitor; and
the sixth base portion, the sixth electrode plates, and the fourth capacitor plate contacts define a portion of the second electrode of the capacitor.

17. The electronic system of claim 16, wherein the capacitor further comprises:
third base contacts extending from the third base portion to the fifth base portion and electrically coupling the third base portion to the fifth base portion; and
fourth base contacts extending from the fourth base portion to the sixth base portion and electrically coupling the fourth base portion to the sixth base portion.

18. The electronic system of claim 14, wherein the first capacitor plate contacts and the second capacitor plate contacts exhibit sloped sidewalls at a first angle, and wherein the third capacitor plate contacts and the fourth capacitor plate contacts exhibit sloped sidewalls at a second angle different from the first angle.

19. The electronic system of claim 10, wherein the first capacitor plate contacts are offset from the second capacitor plate contacts in a direction parallel to the first electrode plates.

20. A method of fabricating a capacitor for an electronic device, the method comprising:
forming first electrode plates of a first capacitor electrode at a first level;
forming first capacitor plate contacts that connect to and extend from the first electrode plates;
forming second electrode plates of a second capacitor electrode at the first level;
forming second capacitor plate contacts that connect to and extend from the second electrode plates;
forming third electrode plates of the first capacitor electrode at a second level and aligned with the first electrode plates, the third electrode plates being formed adjacent to the first capacitor plate contacts, and the first capacitor plate contacts electrically coupling the first electrode plates and the third electrode plates; and
forming fourth electrode plates of the second capacitor electrode at the second level and aligned with the second electrode plates, the fourth electrode plates being formed adjacent to the second capacitor plate contacts, and the second capacitor plate contacts electrically coupling the second electrode plates and the fourth electrode plates.
